(19) United States
(12) Patent Application Publication
(10) Pub. No.: US 2007/0123049 A1
(43) Pub. Date: May 31, 2007

(54) SEMICONDUCTOR PROCESS AND METHOD FOR REMOVING CONDENSED GASEOUS ETCHANT RESIDUES ON WAFER

(76) Inventors: Kao-Su Huang, Tainan County (TW); Ying-Ming Tseng, Kaohsiung City (TW); Chia-Hsun Yu, Tainan City (TW); Chih-Hung Lin, Taipei City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/164,278

(22) Filed: Nov. 17, 2005

(51) Int. Cl. C23F 1/00; H01L 21/461; C03C 15/00; H01L 21/302

(52) U.S. Cl. 438/706; 216/41; 438/718

(57) ABSTRACT

A semiconductor process is provided. A substrate is provided and then a to-be-etched layer is formed on the substrate. A patterned photoresist layer is formed on the to-be-etched layer. The to-be-etching layer is etched using a gaseous etchant to form a patterned layer. In the meantime, some of the gaseous etchant is condensed on the patterned photoresist layer and above the substrate after the etching process. Thereafter, a heat treatment process is performed to remove the condensed gaseous etchant. An ion implanting process is performed to form a doped region in the substrate. After the ion implanting process, the patterned photoresist layer is removed.

### BACKGROUND OF THE INVENTION

1. Field of the Invention

The present invention relates to a semiconductor process. More particularly, the present invention relates to a semiconductor process capable of preventing gaseous etchant from being condensed on a photoresist layer and a substrate and a method for removing condensed gaseous etchant residues from a wafer.

2. Description of the Related Art

In the process of fabricating a polysilicon gate, hydrogen bromide (HBr) is commonly used as a gaseous etchant for etching the polysilicon layer. After the etching process, some residual gaseous etchant in contact with air may be condensed on the surface of the photoresist layer above the wafer. In a subsequent ion implanting process, the condensed residues on the surface of the photoresist layer may block ions into the desire region.

To prevent the occurrence of the aforementioned problem in the ion implanting process, the photoresist layer together with the condensed gaseous etchant is normally removed after the etching process. However, after removing the photoresist layer, the silicide layer on the polysilicon layer will have a narrower line width and a smaller thickness. Thus, in a subsequent ion implanting process, the implanting ions may punch through the silicide layer leading to a drop in the overall yield of the product.

### SUMMARY OF THE INVENTION

Accordingly, at least one objective of the present invention is to provide a semiconductor process capable of preventing gaseous etchant from being condensed on a photoresist layer and substrate to block the ions in a subsequent ion implanting process after an etching process.

At least a second objective of the present invention is to provide a method of removing the condensed gaseous etchant residues on a wafer. The method includes performing a heat treatment process after an etching process to remove the condensed gaseous etchant residues on the photoresist layer and above the substrate.

To achieve these and other advantages and in accordance with the purpose of the invention, as embodied and broadly described herein, the invention provides a semiconductor process. First, a substrate is provided. Then, a to-be-etched layer is formed on the substrate. Thereafter, a patterned photoresist layer is formed over the to-be-etched layer. Using the patterned photoresist layer as a mask, the to-be-etched layer is etched using a gaseous etchant to form a patterned layer. After the etching process, some gaseous etchant is condensed and deposited on the patterned photoresist layer and above the substrate. Afterward, a heat treatment process is performed to remove the condensed gaseous etchant residues. Then, an ion implanting process is carried out to form a doped region in the substrate. After the ion implanting process, the patterned photoresist layer is removed.

According to the semiconductor process in the embodiment of the present invention, the gaseous etchant is a halogen compound such as hydrogen bromide (HBr). The patterned layer is a gate and the doped region is a source/drain region. The heat treatment process is a hot-baking process or a high-power baking process, for example. In addition, a gas may also pass into the reaction chamber during the heat treatment process. The gas includes oxygen, nitrogen or a mixture of oxygen and nitrogen and the gas flow rate is between about 50 sccm˜150 sccm. In the heat treatment process, the operating temperature is between about 200° C. to 300° C., the pressure is between about 10 mtorr˜20 mtorr and the operating period is between about 5 seconds˜20 seconds.

The present invention also provides a method for removing condensed gaseous etchant residues on a wafer. First, a wafer having some condensed gaseous etchant residues thereon is provided. Then, a heat treatment process is performed to remove the condensed gaseous etchant residues on the wafer.

According to the method for removing condensed gaseous etchant residues in the embodiment of the present invention, the gaseous etchant is a halogen compound such as hydrogen bromide (HBr). The heat treatment process is a hot-baking process or a high-power baking process, for example. In addition, a gas may also pass into the reaction chamber during the heat treatment process. The gas includes oxygen, nitrogen or a mixture of oxygen and nitrogen.

In the present invention, a heat treatment process is performed after an etching process but before an ion implanting process. Hence, condensed gaseous etchant residues on the photoresist layer and above the substrate that might block the ions in a subsequent ion implanting process is removed. Moreover, the condensed gaseous etchant residues can be completely removed if oxygen, nitrogen or a mixture of oxygen and nitrogen is passed into the reaction chamber during the heat treatment process. Because the photoresist layer is present in the ion implanting process, regions not designated for ion implantation is protected against possible damage.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIGS. 1A through 1D are schematic cross-sectional views showing the steps in a semiconductor process according to one embodiment of the present invention.

FIG. 2 is a flow diagram showing the steps for removing condensed gaseous etchant residues from a wafer according to one embodiment of the present invention.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

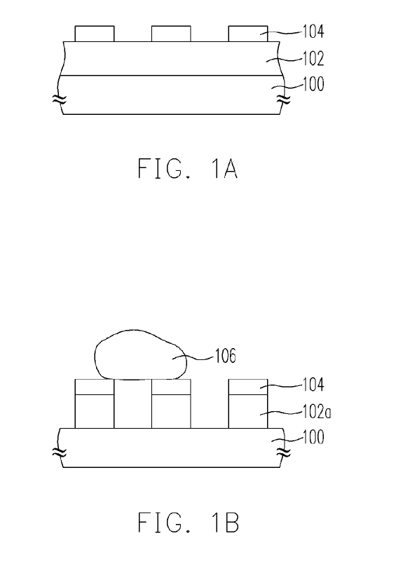

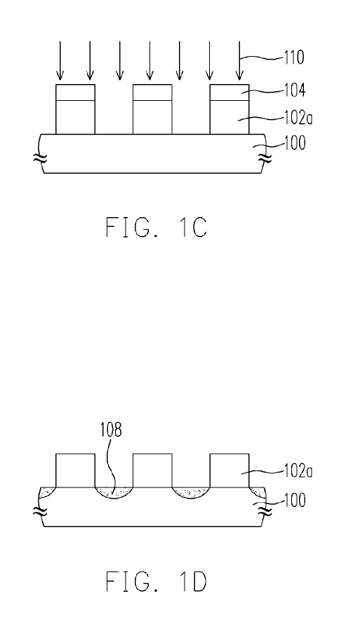

FIGS. 1A through 1D are schematic cross-sectional views showing the steps in a semiconductor process according to one embodiment of the present invention. As shown in FIG. 1 A, a substrate 100 is provided. Then, a to-be-etched layer 102 is formed over the substrate 100. In one embodiment, the to-be-etched layer 102 can be a composite layer comprising a polysilicon layer and a silicide layer for fabricating a gate. Thereafter, a patterned photoresist layer 104 is formed over the to-be-etched layer 102.

As shown in FIG. 1B, using the patterned photoresist layer 104 as a mask, the to-be-etched layer 102 is etched using a gaseous etchant to form a patterned layer 102a. After the etching process, some residual gaseous etchant in contact with air is condensed and deposited on the photoresist layer 104 and the substrate 100. In general, the gaseous etchant is a halogen compound. In one embodiment, the halogen compound is hydrogen bromide (HBr), for example. Afterward, a heat treatment process is performed to remove the condensed gaseous etchant residues 106. The heat treatment process is a hot baking process or a high-power baking process carried out at a temperature between 200° C.˜300° C., a pressure between 10 mtorr˜20 mtorr for a duration of between 5 seconds˜20 seconds. In another embodiment, a gas may be passed into the reaction chamber for performing the heat treatment process at the same time. The gas can be oxygen, nitrogen or a mixture of oxygen and nitrogen having a flow rate between about 50 sccm˜150 sccm, for example.

As shown in FIG. 1C, an ion implanting process 110 is carried out after removing the condensed gaseous etchant residues 106. In one embodiment, the to-be-etched layer 102 is a composite layer having a polysilicon layer and a silicide layer, the present of the patterned photoresist layer 104 on the patterned layer 102a prevents ions in the implanting process from punching through the silicide layer and lowering the production yield. As shown in FIG. 1D, a doped region 108 is formed after the ion implanting process. After that, the patterned photoresist layer 104 is removed. In one embodiment, the doped region 108 is the source/drain region of a transistor, for example.

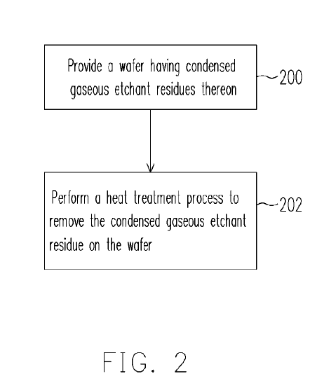

FIG. 2 is a flow diagram showing the steps for removing condensed gaseous etchant residues from a wafer according to one embodiment of the present invention. As shown in FIG. 2, in step 200, a wafer is provided. The wafer has already been subject to an etching process inside an etching chamber and some condensed gaseous etchant residues are deposited on the wafer. In one embodiment, the etching process inside the etching chamber is, for example, a polysilicon gate etching process using a halogen gaseous etchant such as a hydrogen bromide. Thereafter, in step 202, a heat treatment process of the wafer is performed to remove the condensed gaseous etchant residues and prevent the residues from affecting a subsequent process. The heat treatment process is a hot baking process or a high-power baking process, for example. Furthermore, in one embodiment of the present invention, a gas may be passed into the reaction chamber for carrying out the heat treatment process to facilitate the complete removal of the gaseous etchant residues. The gas passed into the reaction chamber includes oxygen, nitrogen or a mixture of oxygen and nitrogen, for example.

In summary, a heat treatment process is performed after an etching process but before an ion implanting process. Hence, condensed gaseous etchant residues on the photoresist layer and the substrate that might block the ions in a subsequent ion implanting process is removed. Moreover, the condensed gaseous etchant residues can be completely removed if oxygen, nitrogen or a mixture of oxygen and nitrogen is passed into the reaction chamber during the heat treatment process. Furthermore, because the photoresist layer is still present when the ion implanting process is performed, regions not designated for ion implantation is protected against possible damage.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A semiconductor process, comprising the steps of:
providing a substrate;
forming a to-be-etched layer on the substrate;
forming a patterned photoresist layer over the to-be-etched layer;
performing an etching process on the to-be-etched layer using the patterned photoresist layer as a mask and a gaseous etchant as an etching agent to form a patterned layer;
performing a heat treatment process to remove condensed gaseous etchant residues formed on the patterned photoresist layer and the substrate after the etching process;
performing an ion implanting process to form a doped region in the substrate; and removing the pattern photoresist layer after the ion implanting process.

2. The semiconductor process of claim 1, wherein the gaseous etchant includes a halogen compound.

3. The semiconductor process of claim 2, wherein the halogen compound comprises hydrogen bromide (HBr).

4. The semiconductor process of claim 1, wherein the heat treatment process includes a hot baking process or a high-power baking process.

5. The semiconductor process of claim 4, wherein the heat treatment process further comprises passing a gas.

6. The semiconductor process of claim 5, wherein the gas includes oxygen, nitrogen or a mixture of oxygen and hydrogen.

7. The semiconductor process of claim 5, wherein the flow rate of the gas is between about 50 sccm˜150 sccm.

8. The semiconductor process of claim 1, wherein the heat treatment process is performed at a temperature between about 200° C. to 300° C.

9. The semiconductor process of claim 1, wherein the heat treatment process is performed at a pressure between about 10 mtorr˜20 mtorr.

10. The semiconductor process of claim 1, wherein the heat treatment process is performed for a duration between about 5 seconds˜20 seconds.

11. The semiconductor process of claim 1, wherein the patterned layer is a gate.

12. The semiconductor process of claim 1, wherein the doped region is a source/drain region.

13. A method of removing condensed gaseous etchant residues on a wafer, comprising the steps of:
providing a substrate having some condensed gaseous etchant residues thereon; and
performing a heat treatment process to remove the condensed gaseous etchant residues on the wafer.

14. The method of claim 13, wherein the gaseous etchant includes a halogen compound.

15. The method of claim 14, wherein the halogen compound includes hydrogen bromide (HBr).

16. The method of claim 13, wherein the heat treatment process includes a hot baking process or a high-power baking process.

17. The method of claim 16, wherein the heat treatment process further comprises passing a gas.

18. The semiconductor process of claim 17, wherein the gas includes oxygen, nitrogen or a mixture of oxygen and hydrogen.
